(19) United States
(12) Patent Application Publication
(10) Pub. No.: US 2023/0317772 A1
(43) Pub. Date: Oct. 5, 2023

(54) SELECTIVE ETCHING OF SILICON LAYERS IN A SEMICONDUCTOR DEVICE

(71) Applicant: MACOM Technology Solutions Holdings, Inc., Lowell, MA (US)

(72) Inventor: Timothy Boles, Lowell, MA (US)

(21) Appl. No.: 17/711,084

(22) Filed: Apr. 1, 2022

(51) Int. Cl. H01L 49/02; H01L 21/3065; H01L 21/308

(52) U.S. Cl. CPC H01L 28/92; H01L 21/3065; H01L 28/91; H01L 21/308

(57) ABSTRACT

Techniques regarding patterning a silicon layer of a semiconductor device are provided. For example, one or more embodiments described herein can regard a method comprising positioning an etch stop layer between a dielectric layer and the silicon layer. Additionally, the method can comprise etching the silicon layer with a chemical etchant. Further, the etching can have a selectivity ratio characterizing etch rates of the silicon layer to the etch stop layer that is at least 200:1.

### FIELD

The subject disclosure relates to patterning one or more silicon layers of a semiconductor device using an etch stop with a highly selective etching process, and more specifically, to one or more semiconductor devices, and/or manufacturing methods thereof, that can comprise a patterned silicon layer (e.g., a doped polysilicon layer) and an etch stop layer having a selectivity of at least 200:1.

### BACKGROUND

In semiconductor device manufacturing, etching processes are used to pattern one or more layers of material. During the etching process targeted portions of the material can be removed from one or more underlying substrates. To prevent over-etching, where the underlying substrate is undesirably degraded by the etching process, an etch stop can be employed. The etch stop can resist the etching processes and shield the underlying substrate. However, etch stops can be difficult to remove after the etching process. Also, the continued presence of the etch stop can inhibit and/or alter the functionality of semiconductor device.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, methods, apparatuses, and/or devices regarding the selective etching of silicon to facilitate manufacturing of one or more semiconductor devices are described.

According to an embodiment, a method for patterning a silicon layer of a semiconductor device is provided. The method can comprise positioning an etch stop layer between a dielectric layer and the silicon layer. The method can also comprise etching the silicon layer with a chemical etchant. Further, the etching can have a selectivity ratio characterizing etch rates of the silicon layer to the etch stop layer that is at least 200:1.

According to another embodiment, a method for selectively etching a silicon layer is provided. The method can comprise depositing an etch stop layer onto a dielectric layer of a semiconductor device. The method can also comprise depositing the silicon layer onto the etch stop layer. Further, the method can comprise performing an etching process on the silicon layer using a chemical etchant. The etch stop layer can shield the dielectric layer from the etching process. Also, the etching process can have a selectivity ratio characterizing etch rates of the silicon layer to the etch stop layer that is at least 200:1.

According to another embodiment, a capacitor is provided. The capacitor can comprise an etch stop layer positioned between a doped polysilicon layer and a plurality of dielectric layers arranged in series on a semiconductor substrate. A selectivity ratio of the doped polysilicon layer to the etch stop layer can be at least 200:1.

### BRIEF DESCRIPTION OF THE DRAWINGS

FIGS. 1A-1D illustrate example, non-limiting stages of a selective etching process that can be employed to pattern one or more silicon layers of a semiconductor device in accordance with one or more embodiments described herein.

FIG. 2 illustrates an example, non-limiting high voltage capacitor during a first stage of manufacturing that can utilize a selective etching process to achieve one or more patterned silicon layers in accordance with one or more embodiments described herein.

FIG. 3 illustrates the example, non-limiting high voltage capacitor during a second stage of manufacturing, where one or more etch stop layers can be deposited in accordance with one or more embodiments described herein.

FIG. 4 illustrates the example, non-limiting high voltage capacitor during a third stage of manufacturing, where one or more silicon layers can be deposited onto the etch stop layer in accordance with one or more embodiments described herein.

FIG. 5 illustrates the example, non-limiting high voltage capacitor during a fourth stage of manufacturing, where one or more mask layers can be utilized to shield select portions of the one or more silicon layers in accordance with one or more embodiments described herein.

FIG. 6 illustrates the example, non-limiting high voltage capacitor during a fifth stage of manufacturing, where one or more exposed portions of the silicon layers can be selectively etched in accordance with one or more embodiments described herein.

FIG. 7 illustrates the example, non-limiting high voltage capacitor during a sixth stage of manufacturing, where the one or more mask layers can be removed in to expose the pattered silicon layers in accordance with one or more embodiments described herein.

FIG. 8 illustrates the example, non-limiting high voltage capacitor during a seventh stage of manufacturing, where one or more top plate components can be deposited onto the patterned silicon layers in accordance with one or more embodiments described herein.

FIG. 9 illustrates another example, non-limiting high voltage capacitor that can be manufactured using one or more selective etching processes in accordance with one or more embodiments described herein.

FIG. 10 illustrates a flow diagram of an example, non-limiting selective etching process that can be employed to pattern one or more silicon layers of a semiconductor device in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section. Additionally, features depicted in the drawings with like shading, cross-hatching, and/or coloring can comprise shared compositions and/or materials.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various semiconductor devices comprise one or more silicon layers to achieve a desired architecture. Further, the silicon layers can be patterned to achieve a desired geometry, dimension, and/or layout. The silicon layers can traditionally be patterned via an etching process that uses an etchant to chemically react with, and remove, exposed portions of the silicon layers. However, the etching process can also interact with other components of the semiconductor device; thereby removing and/or degrading material other than the silicon layers. Some etching techniques can employ an etch stop to mitigate excessive etching; however, traditional etch stops comprise materials that can inhibit the function of one or more adjacent components in the semiconductor device.

For instance, high voltage capacitors can comprise a top plate composed of doped polysilicon positioned adjacent to a stack of dielectric layers, where the stack of dielectric layers can define the electrical capacitance of the capacitor. Traditional techniques for patterning the doped polysilicon utilize a lift off metal as a mask, where exposed portions of the doped polysilicon are then etched away using a chemical etchant. However, the etching can also remove a portion of the one or more dielectric layers and compromise the uniformity of the stack of dielectric layers, thereby compromising both the capacitance and the leakage/breakdown voltage capability of the capacitor. Additionally, traditional etching techniques can cause deviations in the sidewalls of the remaining doped polysilicon. Further, traditional etching techniques can leave the doped polysilicon layer with irregular foundation geometries at the interface with the stack of dielectric layers.

Various embodiments described herein can regard patterning one or more silicon layers (e.g., doped polysilicon) via a selective etching process that utilizes an etch stop layer (e.g., hafnium oxide) and a selectivity ratio of at least 200:1. For instance, the etch stop layer can be positioned between the one or more silicon layers and one or more dielectric layers in a semiconductor device. The etch stop layer can shield the one or more dielectric layers during a selective etching process. Due to at least the high selectivity ratio, the silicon layer can be patterned using a chemical etchant without compromising the integrity of the one or more dielectric layers positioned under the etch stop layer. Additionally, in one or more embodiments, the etch stop layer can have a dielectric constant that is greater than one or more of the respective dielectric layers. Thereby, electrical permittivity within the semiconductor device can remain a function of the dielectric layers, rather than being inhibited by the presence of the etch stop layer.

For instance, one or more embodiments described herein can regard a kilovolt (KV) capacitor that can comprise a doped polysilicon top plate patterned via a selective etching process. Further, the KV capacitor can comprise an etch stop layer positioned between the doped polysilicon and a stack of dielectric layers arranged in series on a semiconductor substrate, where the doped polysilicon layer can be patterned via a selective etching process that implements a selectivity ratio of at least 200:1. In one or more examples, the etch stop layer can further have a dielectric constant that is greater than one or more of the respective dielectric constants of the dielectrics comprised within the stack of dielectric layers. Example materials that can comprise the etch stop layer can include, but are not limited to: hafnium oxide, zirconium oxide, a combination thereof, and/or the like.

As described herein, the terms “deposition process” and/or “deposition processes” can refer to any process that grows, coats, deposits, and/or otherwise transfers one or more first materials onto one or more second materials. Example deposition processes can include, but are not limited to: physical vapor deposition (“PVD”), chemical vaper deposition (“CVD”), electrochemical deposition (“ECD”), atomic layer deposition (“ALD”), low-pressure chemical vapor deposition (“LPCVD”), plasma enhanced chemical vapor deposition (“PECVD”), high density plasma chemical vapor deposition (“HDPCVD”), sub-atmospheric chemical vapor deposition (“SACVD”), rapid thermal chemical vapor deposition (“RTCVD”), in-situ radical assisted deposition, high temperature oxide deposition (“HTO”), low temperature oxide deposition (“LTO”), limited reaction processing CVD (“LRPCVD”), ultrahigh vacuum chemical vapor deposition (“UHVCVD”), metalorganic chemical vapor deposition (“MOCVD”), physical vapor deposition (“PVD”), chemical oxidation, sputtering, plating, evaporation, spin-on-coating, ion beam deposition, electron beam deposition, laser assisted deposition, chemical solution deposition, a combination thereof, and/or the like.

As described herein, the terms “epitaxial growth process” and/or “epitaxial growth processes” can refer to any process that grows an epitaxial material (e.g., a crystalline semiconductor material) on a deposition surface of another semiconductor material, in which the epitaxial material being grown has substantially the same crystalline characteristics as the semiconductor material of the deposition surface. In an epitaxial deposition process, chemical reactants provided by source gases (e.g., a silicon and/or germanium containing gas) and/or source liquids can be controlled, and the system parameters can be set, so that the depositing atoms arrive at the deposition surface with sufficient energy to move about on the surface and orient themselves to the crystal arrangement of the atoms of the deposition surface. Therefore, the grown epitaxial material has substantially the same crystalline characteristics as the deposition surface on which the epitaxial material is formed. For example, an epitaxially grown semiconductor material deposited on a <100> orientated crystalline surface can take on a <100> orientation. Example epitaxial growth processes can include, but are not limited to: vapor-phase epitaxy (“VPE”), molecular-beam epitaxy (“MBE”), liquid-phase epitaxy (“LPE”), a combination thereof, and/or the like.

As described herein, the terms “lithography process” and/or “lithography processes” can refer to the formation of three-dimensional relief images or patterns on a semiconductor substrate for subsequent transfer of the pattern to the substrate. In semiconductor lithography, the patterns can be formed by a light sensitive polymer called a photo-resist. To build the complex structures that make up a semiconductor device and the many wires that connect the various features of a circuit, lithography processes and/or etch pattern transfer steps can be repeated multiple times. Each pattern being printed on the wafer can be aligned to the previously formed patterns and slowly the subject features (e.g., conductors, insulators and/or selectively doped regions) can be built up to form the final device.

As described herein, the terms “etching process” and/or “etching processes” can refer to any process that removes one or more first materials from one or more second materials. For instant, etching processes can utilize one or more chemical etchants to remove material via a chemical interaction. Example etching processes can include, but are not limited to: wet etching, dry etching, plasma etching (e.g., reactive-ion etching (“RIE”), deep reactive-ion etching (“DRIE”), inductively coupled plasma (“ICP”), atomic layer etching (“ALE”), reactive ion beam milling, and/or the like), chemical-mechanical planarization (“CMP”), a combination thereof, and/or the like.

As described herein, the term “selectivity ratio” can refer to a ratio of etch rates between materials during an etching process. In particular, the selectivity ratio can be a ratio of the etch rate of a material to be removed during a given etching process to the etch rate of another material that is to remain during the etching process. For instance, a selectivity ratio characterizing doped polysilicon to hafnium oxide can describe an etching process where one or more portions of the doped polysilicon are removed while the hafnium oxide remains in a semiconductor device.

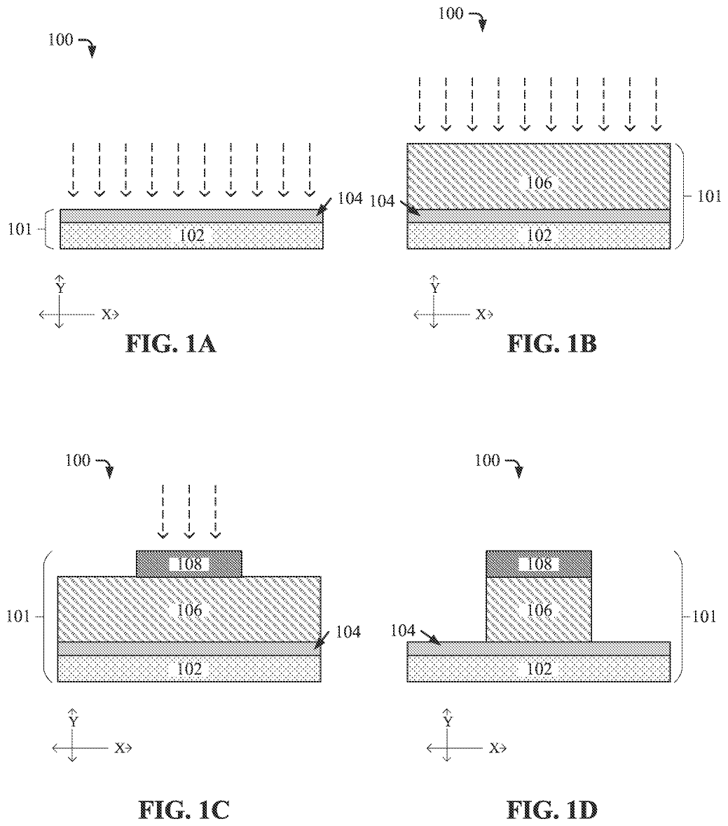

FIGS. 1A-1D illustrate diagrams of an example, non-limiting selective etching process 100 that can be utilized to facilitate manufacturing of a semiconductor device 101 in accordance with one or more embodiments described herein. FIGS. 1A-1D show a cross-section of an example semiconductor device 101 that can comprise one or more dielectric layers 102, etch stop layers 104, and/or silicon layers 106. The selective etching process 100 can be utilized to pattern the one or more silicon layers 106 while maintaining the integrity and/or functional capacity of the one or more dielectric layers 102. FIGS. 1A-1C can depict one or more deposition processes via dashed arrows.

In accordance with various embodiments described herein, FIGS. 1A-1D can show a portion of the example semiconductor device 101 to demonstrate one or more features of the selective etching process 100. However, implementation of the selective etching process 100 is not limited to the semiconductor device 101 architecture shown in FIGS. 1A-1D. For instance, the example semiconductor device 101 can comprise additional materials, layers, and/or components in accordance with one or more embodiments described herein.

FIG. 1A depicts a first stage of the selective etching process 100. As shown in FIG. 1A, one or more etch stop layers 104 can be deposited onto one or more dielectric layers 102 that are to be shielded from one or more chemical etchants. In various embodiments, the one or more etch stop layers 104 can be deposited via one or more deposition processes that can provide a continuous and pinhole free conformality of the one or more etch stop layers 104 over non-planar topologies. For instance, although the one or more dielectric layers 102 are shown as substantially planar in FIGS. 1A-1D, embodiments in which the one or more dielectric layers 102 have a non-planar topology are also envisaged. In various embodiments, the one or more etch stop layers 104 can be deposited via one or more ALD, LPCVD, and/or PECVD processes.

In various embodiments, the one or more etch stop layers 104 can be deposited across the entirety, or substantially the entirety, of the one or more dielectric layers 102. For example, as shown in FIG. 1A, the one or more etch stop layers 104 can be deposited across the width (e.g., along the X axis shown in FIG. 1A) of the one or more dielectric layers 102. In one or more embodiments, the one or more etch stop layers 104 can be deposited onto portions of the one or more dielectric layers 102 to be shielded from chemical etchants.

FIG. 1B depicts a second stage of the selective etching process 100. As shown in FIG. 1B, one or more silicon layers 106 can be deposited onto the one or more etch stop layers 104 via one or more deposition processes. In various embodiments, the one or more silicon layers 106 can have various levels of purity based on the function and/or application of the semiconductor device 101. For example, the one or more silicon layers 106 can be one or more layers of polysilicon. Additionally, in various embodiments, the one or more silicon layers 106 can comprise one or more dopants depending on the function and/or application of the semiconductor device 101. For instance, the one or more silicon layers 106 can be doped to modify one or more electrical properties. Selective doping can enable the conductivity of the substrate (e.g., silicon layers 106) to be changed with the application of voltage. Example dopants can include, but are not limited to: phosphorus, arsenic, antimony, boron, gallium, aluminum, a combination thereof, and/or the like. For instance, phosphorus oxychloride can be used as a liquid dopant precursor for n-type doping. In one or more embodiments, the one or more silicon layers 106 can be one or more doped polysilicon layers.

In various embodiments, the material composition of the one or more etch stop layers 104 can be selected based on: the selectivity ratio of the one or more silicon layers 106 to the one or more etch stop layers 104 (e.g., based on the etchant chemistry employed by the selective etching process 100); and/or the dielectric constant of the one or more dielectric layers 102. For example, the selectivity ratio of the one or more silicon layers 106 to etch stop layers 104 can be at least 200:1. For instance, the selectivity ratio can be greater than or equal to 200:1 and less than or equal to 1000:1. In one or more embodiments, the selectivity ratio of the one or more silicon layers 106 to the one or more etch stop layers 104 can approach infinity. Additionally, the one or more etch stop layers 104 can have a greater dielectric constant than one or more individual layers of the one or more dielectric layers 102 (e.g., the one or more etch stop layers 104 can have a greater dielectric constant value than any and/or all of the one or more dielectric layers 102, respectively). For instance, the one or more etch stop layers 104 can have a dielectric constant ranging from, for example, greater than or equal to 20 and less than or equal to 100. Example materials that can comprise the one or more etch stop layers 104 can include, but are not limited to: hafnium oxide (HfO₂), zirconium oxide (ZrO₂), a combination thereof, and/or the like. For instance, the one or more etch stop layers 104 can be one or more hafnium oxide layers.

FIG. 1C depicts a third stage of the selective etching process 100. As shown in FIG. 1C, one or more mask layers 108 can be deposited onto the one or more silicon layers 106 via one or more deposition processes. The one or more mask layers 108 can be selectively positioned onto portions of the one or more silicon layers 106 that are to be shielded from one or more chemical etchants. In one or more embodiments, the one or more mask layers 108 can be one or more layers of photoresist material patterned via one or more lithography processes. Example materials that can comprise the one or more mask layers 108 can include, but are not limited to: photoresist, benzocyclobutane (“BCB”) polyimide, metallic layers, a combination thereof, and/or the like.

FIG. 1D depicts a fourth stage of the selective etching process 100. As shown in FIG. 1D, one or more portions of the one or more silicon layers 106 can be etched away using one or more chemical etchants. Portions of the one or more silicon layers 106 not covered by the one or more mask layers 108 can be exposed to the chemical etching; whereas one or more portions of the one or more silicon layers 106 covered by the one or more mask layers 108 can be shielded from the chemical etching. The one or more silicon layers 106 can be etched using one or more etching processes that employ etchants to chemically interact with the one or more silicon layers 106 to remove one or more portions of the one or more silicon layers 106 from the one or more etch stop layers 104. In various embodiments, the one or more etch stop layers 104 can be substantially chemically inactive with regards to the chemical etchant; thereby, the one or more etch stop layers 104 can shield the underlying dielectric layers 102 from the chemical etchant.

In various embodiments, the one or more silicon layers 106 can be etched via one or more wet etching and/or plasma etching processes (e.g., RIE, DRIE, ICP, ALE, reactive ion beam milling, a combination thereof, and/or the like). Further, the etching can be anisotropic. Example etchants that can be utilized in the selective etching process 100 to etch the one or more silicon layers 106 can include, but are not limited to: nitric acid (HNO₃)/hydrofluoric acid (HF) mixtures, potassium hydroxide (KOH), ethylenediamine pyrocatechol (EDP), tetramethylammonium hydroxide (TMAH), carbon tetrafluoride (CF₄), sulfur hexafluoride (SF₆), nitrogen trifluoride (NF₃), chloride (Cl₂), dichlorodifluoromethane (CCl₂F₂), a combination thereof, and/or the like.

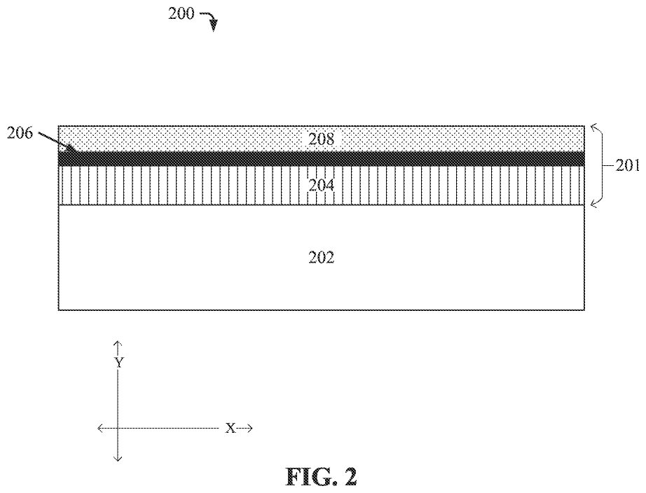

FIG. 2 illustrates a diagram of an example, non-limiting KV capacitor 200 during a first stage of manufacturing in accordance with one or more embodiments described herein. Repetitive description of like elements employed in other embodiments described herein is omitted for the sake of brevity. FIG. 2 depicts a cross-section of the KV capacitor 200. In various embodiments, the KV capacitor 200 can be a non-limiting example embodiment of the semiconductor device 101. Further, one or more aspects of the KV capacitor 200 can be manufactured using the selective etching process 100.

As shown in FIG. 2, the KV capacitor 200 can comprise a dielectric stack 201 positioned on a semiconductor substrate 202. In various embodiments, the semiconductor substrate 202 can be crystalline, semi-crystalline, microcrystalline, or amorphous. The semiconductor substrate 202 can comprise essentially (e.g., except for contaminants) a single element (e.g., silicon or germanium) and/or a compound (e.g., aluminum oxide, silicon dioxide, gallium arsenide, silicon carbide, silicon germanium, a combination thereof, and/or the like). The semiconductor substrate 202 can also have multiple material layers, such as, but not limited to: a semiconductor-on-insulator substrate (“SeOI”), a silicon-on-insulator substrate (“SOI”), germanium-on-insulator substrate (“GeOI”), silicon-germanium-on-insulator substrate (“SGOI”), a combination thereof, and/or the like. Additionally, the semiconductor substrate 202 can also have other layers, such as oxides with high dielectric constants (“high-K oxides”) and/or nitrides. In one or more embodiments, the semiconductor substrate 202 can be a silicon wafer. In various embodiments, the semiconductor substrate 202 can comprise a single crystal silicon (Si), silicon germanium (e.g., characterized by the chemical formula SiGe), a Group III-V semiconductor wafer or surface/active layer, a combination thereof, and/or the like. In one or more embodiments, the semiconductor substrate 202 can be doped silicon.

The dielectric stack 201 can comprise one or more dielectric layers 102 arranged in series (e.g., along the Y axis shown in FIG. 2). For example, the dielectric stack 201 can comprise one or more dielectric layers 102, such as one or more high pressure oxidation (“HiPOX”) layers 204 formed on the surface of the semiconductor substrate 202 via one or more thermal oxidation processes. For instance, the one or more HiPOX layers 204 can be silicon dioxide (SiO₂) layers formed on the surface of the semiconductor substrate 202. Additionally, the dielectric stack 201 can comprise one or more dielectric layers 102, such as one or more moisture seal layers 206 positioned on the one or more HiPOX layers 204. For instance, the one or more moisture seal layers 206 can comprise a silicon nitride (e.g., SiN or Si₃N₄), which can be deposited via one or more LPCVD processes. Further, the dielectric stack 201 can comprise one or more dielectric layers 102, such as one or more low temperature oxide (“LTO”) layers 208, which can be positioned onto the one or more moisture seal layers 206 via one or more deposition processes. Example materials that can comprise the one or more LTO layers 208 can include, but are not limited to: aluminum oxide (Al₂O₃), In various embodiments, the one or more etch stop layers 104 can have a dielectric constant that is greater than or equal to that of the dielectric layer 102 of the dielectric stack 201 having the lowest dielectric constant value. Additionally, the total capacitance of the KV capacitor 200 can be a function of the series capacitance contribution of each dielectric of the dielectric stack 201 and/or the etch stop layer 104.

In one or more embodiments, the one or more HiPOX layers 204 can have a thickness (e.g., along the Y axis shown in FIG. 2) ranging from, for example, greater than or equal to 5,000 Å and less than or equal to 45,000 Å (e.g., 2.45 μm). The one or more moisture seal layers 206 can have a thickness (e.g., along the Y axis shown in FIG. 2) ranging from, for example, greater than or equal to 250 Å and less than or equal to 5,000 Å (e.g., 500 Å). Also, the one or more LTO layers 208 can have a thickness (e.g., along the Y axis shown in FIG. 2) ranging from, for example, greater than or equal to 1,000 Å and less than or equal to 10,000 Å (e.g., 1,000 Å).

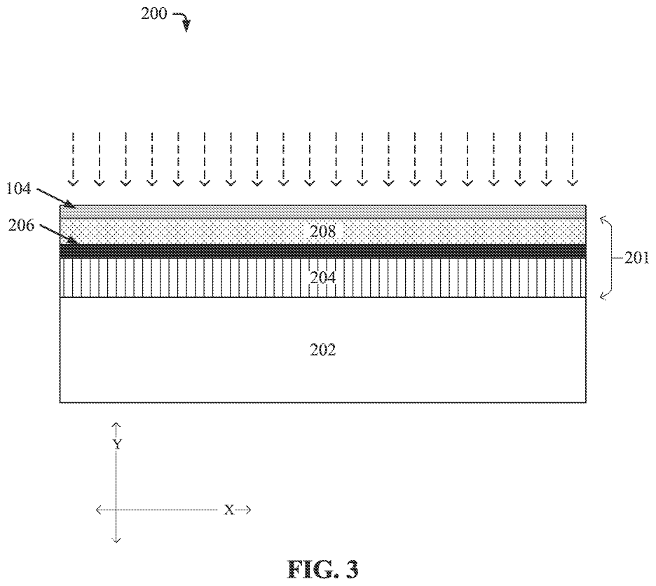

FIG. 3 illustrates a diagram of the example, non-limiting KV capacitor 200 during a second stage of manufacturing in accordance with one or more embodiments described herein. Repetitive description of like elements employed in other embodiments described herein is omitted for the sake of brevity. FIG. 3 also depicts a cross-section of the KV capacitor 200. As shown in FIG. 3, one or more etch stop layers 104 can be deposited onto the dielectric stack 201 via one or more deposition process (e.g., as depicted by the dashed arrows in FIG. 3) in accordance with the first stage of the selective etching process 100. For instance, the one or more etch stop layers 104 can be deposited via one or more ALD processes.

In accordance with various embodiments described herein, the one or more etch stop layers 104 can have a high dielectric constant (e.g., greater than or equal to 20). In one or more embodiments, the one or more etch stop layers 104 can have a dielectric constant that is greater than or equal to the dielectric constant of the HiPOX layer 204. Example materials that can comprise the one or more etch stop layers 104 include, but are not limited to: hafnium oxide, zirconium oxide, a combination thereof, and/or the like. For instance, the one or more etch stop layers 104 can be one or more layers of hafnium oxide. A thickness (e.g., along the Y axis shown in FIG. 3) of the one or more etch stop layers 104 can vary depending on: the etchant implemented in a subsequent stage of the selective etching process 100; and/or the application of the KV capacitor 200. For instance, the thickness (e.g., along the Y axis shown in FIG. 3) of the one or more etch stop layers 104 can range from, for example, greater than or equal to 50 Å and less than or equal to 1,000 Å (e.g., 150 Å). Thereby, in various embodiments the one or more etch stop layers 104 can be a thin, conformal layer of material having a high dielectric constant (e.g., with reference to the dielectric layers 102 of the dielectric stack 201) and high selectivity ratio (e.g., characterizing the one or more silicon layers 106 to etch stop layers 104).

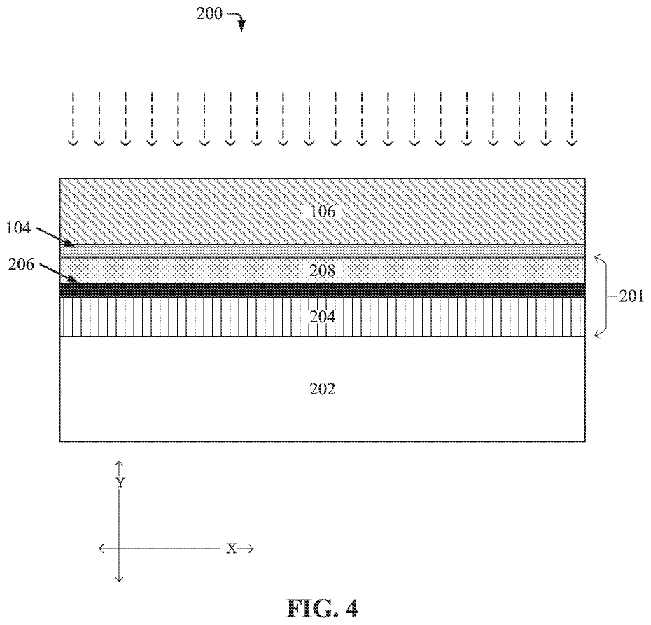

FIG. 4 illustrates a diagram of the example, non-limiting KV capacitor 200 during a third stage of manufacturing in accordance with one or more embodiments described herein. Repetitive description of like elements employed in other embodiments described herein is omitted for the sake of brevity. As shown in FIG. 4, one or more silicon layers 106 can be deposited (e.g., via one or more deposition processes, such as LPCVD) onto the one or more etch stop layers 104 in accordance with a second stage of the selective etching process 100. In various embodiments, the one or more silicon layers 106 can be one or more layers of doped polysilicon that can serve as a top plate for the KV capacitor 200. Also, the one or more silicon layers 106 can have a thickness (e.g., along the Y axis) ranging from, for example, greater than or equal to 0.5 microns (μm) and less than or equal to 8 μm (e.g., 5 μm).

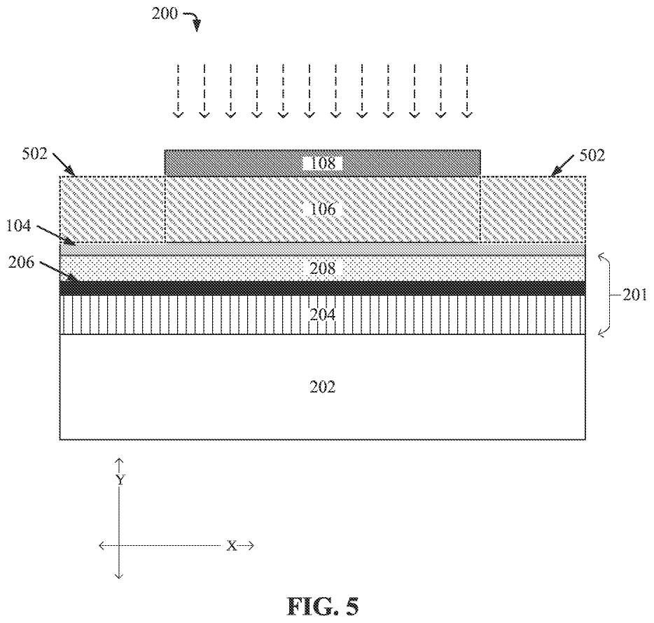

FIG. 5 illustrates a diagram of the example, non-limiting KV capacitor 200 during a fourth stage of manufacturing in accordance with one or more embodiments described herein. Repetitive description of like elements employed in other embodiments described herein is omitted for the sake of brevity. As shown in FIG. 5, one or more mask layers 108 can be deposited onto the one or more silicon layers 106 in accordance with a third stage of the selective etching process 100.

In various embodiments, the one or more mask layers 108 can be deposited and/or patterned (e.g., via one or more lithography processes) onto targeted portions of the one or more silicon layers 106 (e.g., as shown in FIG. 5). For instance, the one or more mask layers 108 can be a photoresist material. Portions of the one or more silicon layers 106 directly underlying the one or more mask layers 108 (e.g., along the Y axis shown in FIG. 5) can be shielded from one or more etchants subsequently employed. In contrast, exposed portions 502 (e.g., denoted with dotted lines) of the one or more silicon layers 106 can be portions not covered by the one or more mask layers 108 and thereby exposed to the one or more subsequent etchants. The one or more mask layers 108 can have a thickness (e.g., along the Y axis) ranging from, for example, greater than or equal to 2 μm and less than or equal to 10 μm.

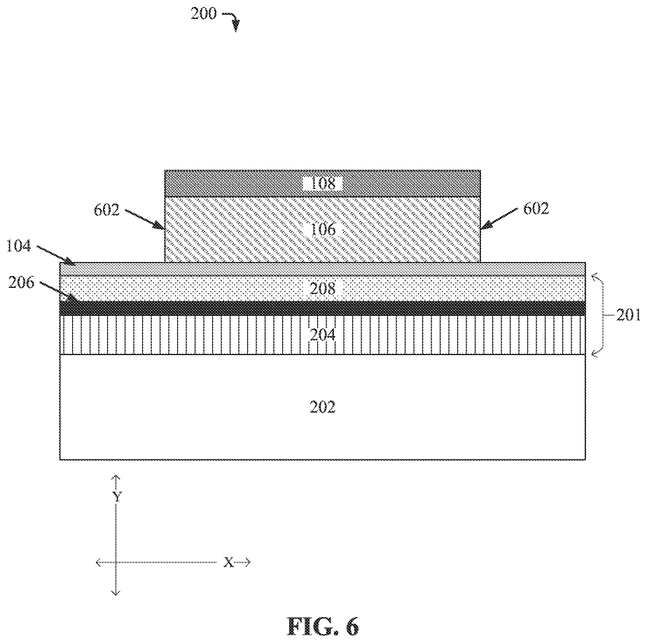

FIG. 6 illustrates a diagram of the example, non-limiting KV capacitor 200 during a fifth stage of manufacturing in accordance with one or more embodiments described herein. Repetitive description of like elements employed in other embodiments described herein is omitted for the sake of brevity. As shown in FIG. 6, the exposed portions 502 of the one or more silicon layers 106 can be etched away from the one or more etch stop layers 104 using a chemical etchant in accordance with the fourth stage of the selective etching process 100.

In various embodiments, the exposed portions 502 of the one or more silicon layers 106 can be etched using a plasma etching technique. For example, RIE and/or DRIE can be employed using a chemical etchant such as sulfur hexafluoride and/or chloride. As shown in FIG. 6, the selective etching process 100 can remove the one or more exposed portions 502 of the one or more silicon layers 106 (e.g., doped polysilicon) completely down to the one or more etch stop layers 104 (e.g., hafnium oxide). Also shown in FIG. 6, the selective etching process 100 can render smooth, substantially uniform sidewalls 602 for the remaining portions of the silicon layers 106. For instance, the sidewalls 602 can be perpendicular, or substantially perpendicular, to the one or more etch stop layers 104 through the thickness (e.g., along the Y axis shown in FIG. 6) of the remaining portions of the silicon layers 106 (e.g., as exemplified in FIG. 6). Additionally, the one or more etch stop layers 104 can protect the dielectric stack 201 from the etching of the one or more silicon layers 106.

Further, the electrical breakdown capability of the KV capacitor 200 can be enhanced by the presence of the one or more etch stop layers 104 (e.g., due to at least the high dielectric constant of the one or more etch stop layers 104), even where the one or more etch stop layers 104 have a small thickness (e.g., along the Y axis show in FIG. 6) value (e.g., 150 Å). For example, the one or more etch stop layers 104 can contribute to series capacitance with the dielectric stack 201. For instance, one or more embodiments can comprise hafnium oxide as the one or more etch stop layers 104, where the field strength of the one or more etch stop layers 104 can increase with a reduction of thickness and contribute to an electrical breakdown voltage for the KV capacitor 200 of greater than, for example, 1,600 volts (V).

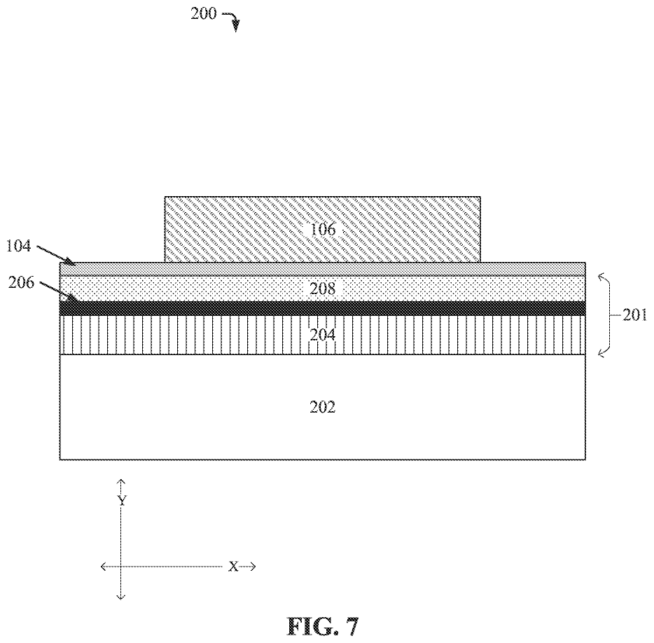

FIG. 7 illustrates a diagram of the example, non-limiting KV capacitor 200 during a sixth stage of manufacturing in accordance with one or more embodiments described herein. Repetitive description of like elements employed in other embodiments described herein is omitted for the sake of brevity. As shown in FIG. 7, the one or more mask layers 108 can be removed from the one or more silicon layers 106. In various embodiments, the one or more mask layers 108 can be removed via one or more etching processes such as wet etching, dry etching, plasma etching, chemical-mechanical planarization (“CMP”), a combination thereof, and/or the like.

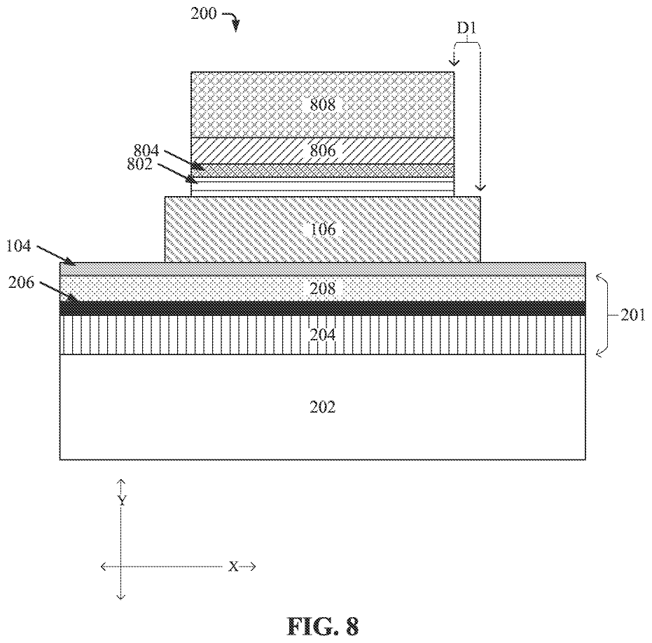

FIG. 8 illustrates a diagram of the example, non-limiting KV capacitor 200 during a seventh stage of manufacturing in accordance with one or more embodiments described herein. Repetitive description of like elements employed in other embodiments described herein is omitted for the sake of brevity. As shown in FIG. 8, one or more metal layers can be deposited onto the one or more silicon layers 106 via one or more deposition processes.

As shown in FIG. 8, the metal layers can comprise a first metal layer 802, a second metal layer 804, a third metal layer 806, and/or a fourth metal layer 808. In one or more embodiments, the first metal layer 802 can be a film grown on the one or more silicon layers 106 via one or more epitaxial growth processes. Example materials that can comprise the first metal layer 802 can include, but are not limited to: epitaxial Pd₂Si, PtSi, CoSi₂, a combination thereof, and/or the like. The one or more first metal layers 802 can have a thickness (e.g., along the Y axis) ranging from, for example, greater than or equal to 50 Å and less than or equal to 1,000 Å (e.g., 750 Å).

In various embodiments, the second metal layer 804 can comprise a metal deposited onto the first metal layer 802 via one or more deposition processes. Further, the third metal layer 806 can comprise a metal deposited onto the second metal layer 804 via one or more deposition processes. Also, the fourth metal layer 808 can comprise a metal deposited onto the third metal layer 806 via one or more deposition processes. Example metals that can comprise the second metal layer 804, the third metal layer 806, and/or the fourth metal layer 808 can include, but are not limited to: titanium, platinum, gold, copper, silver, nickel, chrome, titanium tungsten composites (e.g., TiW, TiWN, and/or TiWO), a combination thereof, and/or the like. In one or more embodiments, each metal layer can comprise a respective metal. For instance, the second metal layer 804 can comprise titanium, the third metal layer 806 can comprise platinum, and/or the fourth metal layer 808 can comprise gold.

In one or more embodiments, the second metal layer 804 can have a thickness (e.g., along the Y axis) ranging from, for example, greater than or equal to 250 Å and less than or equal to 1,000 Å (e.g., 500 Å). The third metal layer 806 can have a thickness (e.g., along the Y axis) ranging from, for example, greater than or equal to 500 Å and less than or equal to 2,000 Å (e.g., 1000 Å). Also, the one or more fourth metal layers 808 can have a thickness (e.g., along the Y axis) ranging from, for example, greater than or equal to 0.8 μm and less than or equal to 5.0 μm (e.g., 3.0 μm).

Also shown in FIG. 8, a periphery of the metal layers (e.g., first metal layer 802, second metal layer 804, third metal layer 806, and/or fourth metal layer 808) can be set back from the periphery of the one or more silicon layers 106 by a defined distance D1 (e.g., along the X axis shown in FIG. 8). The distance D1 can range from, for example, greater than or equal to 3 μm and less than or equal to 15 μm.

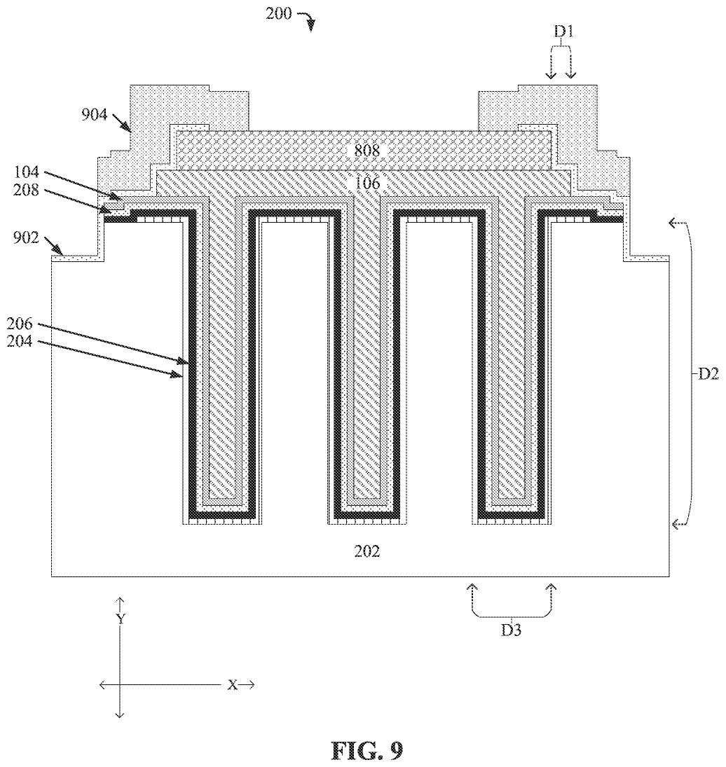

FIG. 9 illustrates a diagram of an example, non-limiting embodiment of the KV capacitor 200 in accordance with one or more embodiments described herein. Repetitive description of like elements employed in other embodiments described herein is omitted for the sake of brevity. FIG. 9 depicts cross-sectional view of an example architecture of the KV capacitor 200 that can be manufactured using the selective etching process 100. For instance, the exemplary KV capacitor 200 architecture shown in FIG. 9 can comprise one or more etch stop layers 104 positioned between one or more dielectric stacks 201 (e.g., comprising one or more dielectric layers 102, such as: HiPOX layers 204, moisture seal layers 206, and/or LTO layers 208) and one or more silicon layers 106 (e.g., doped polysilicon).

As shown in FIG. 9, the one or more dielectric stacks 201 can extend into one or more trenches formed within the semiconductor substrate 202. In one or more embodiments, the semiconductor substrate 202 can be a low resistivity silicon substrate. In various embodiments, the one or more trenches can have a depth D2 (e.g., along the Y axis) ranging from, for example, greater than or equal to 20 μm and less than or equal to 200 μm. Also, the one or more trenches can have a width D3 (e.g., along the X axis) ranging from, for example, greater than or equal to 4 μm and less than or equal to 10 μm. Although FIG. 9 depicts an exemplary embodiment comprising three trenches, embodiments comprising less than three trenches or more than three trenches are also envisaged.

In various embodiments, the one or more etch stop layers 104 can be deposited continuously over the one or more dielectric stacks 201. For example, the one or more etch stop layers 104 can be deposited via one or more ALD, LPCVD, and/or PECVD processes to facilitate deposition within the one or more trenches in the semiconductor substrate 202.

In one or more embodiments, the KV capacitor 200 can comprise a single metal layer positioned on the one or more silicon layers 106. For example, FIG. 9 depicts an example embodiment in which the fourth metal layer 808 (e.g., gold) is deposited directly onto the one or more silicon layers 106. Further, one or more silicon nitride layers 902 can be deposited (e.g., via one or more deposition processes, such as PECVD) onto one or more portions of: the semiconductor substrate 202, the one or more etch stop layers 104, the one or more silicon layers 106, and/or the metal layers (e.g., fourth metal layer 808). The one or more silicon nitride layers 902 can have the same, or substantially the same, material composition as the one or more moisture seal layers 206. Alternatively, the one or more silicon nitride layers 902 can have a different material composition than the one or more moisture seal layers 206. Additionally, one or more BCB layers 904 can be positioned on a portion of the one or more silicon nitride layers 902 and/or metal layers (e.g., fourth metal layer 808). In various embodiments, the one or more BCB layers 904 can facilitate one or more bonding operations and/or electronic properties.

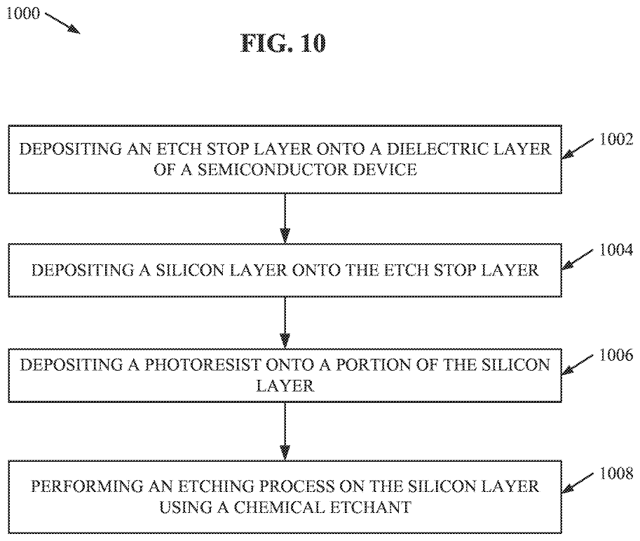

FIG. 10 illustrates a flow diagram of an example, non-limiting method 1000 that can be employed to pattern one or more silicon layers 106 and/or manufacture one or more semiconductor devices 101 (e.g., KV capacitor 200) in accordance with one or more embodiments described herein. Repetitive description of like elements employed in other embodiments described herein is omitted for the sake of brevity.

At 1002, the method 1000 can comprise depositing (e.g., via one or more deposition processes, such as ALD) one or more etch stop layers 104 onto one or more dielectric layers 102 of a semiconductor device 101 (e.g., in accordance with the first stage of the selective etching process 100). In various embodiments, the one or more etch stop layers 104 can have a dielectric constant value greater than or equal to the dielectric constant value of the one or more of the dielectric layers 102.

At 1004, the method 1000 can comprise depositing (e.g., via one or more deposition processes, such as LPCVD) one or more silicon layers 106 onto the one or more etch stop layers 104. In various embodiments, the one or more silicon layers 106 can be one or more layers of doped polysilicon. Additionally, a selectivity ratio of the one or more silicon layers 106 to etch stop layers 104 can be greater than or equal to 200:1.

At 1006, the method 1000 can comprise depositing (e.g., via one or more lithographic processes) a photoresist (e.g., mask layer 108) onto a portion of the one or more silicon layers 106. At 1008, the method 1000 can comprise performing one or more etching processes on the one or more silicon layers 106 using one or more chemical etchants. In various embodiments, the one or more etching processes can be one or more plasma etching processes (e.g., RIE). During the etching at 1008, the one or more etch stop layers 104 can shield the one or more dielectric layers 102 from the chemical etchant, and the photoresist can shield one or more portions of the one or more silicon layers 106 from the chemical etchant.

It is, of course, not possible to describe every conceivable combination of components, products and/or methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

What is claimed is:

1. A method for patterning a silicon layer of a semiconductor device, the method comprising:
positioning an etch stop layer between a dielectric layer and the silicon layer; and
etching the silicon layer with a chemical etchant, wherein the etching has a selectivity ratio characterizing etch rates of the silicon layer to the etch stop layer of at least 200:1.

2. The method of claim 1, wherein a dielectric constant of the etch stop layer is greater than or equal to a dielectric constant of the dielectric layer.

3. The method of claim 2, wherein the semiconductor device is a capacitor, wherein the silicon layer is a top plate of the capacitor comprising doped polysilicon, and wherein the dielectric layer is comprised within a stack of dielectrics arranged in series.

4. The method of claim 2, wherein the etch stop layer comprises at least one material selected from the group consisting of hafnium oxide and zirconium oxide.

5. The method of claim 4, wherein the material is hafnium oxide, and wherein the silicon layer comprises doped polysilicon.

6. The method of claim 1, wherein the etching comprises a plasma etching process to selectively remove one or more portions of the silicon layer.

7. The method of claim 1, further comprising:
depositing the etch stop layer onto the dielectric layer via an atomic layer deposition process.

8. The method of claim 1, further comprising:
depositing the etch stop layer via a deposition process that provides a continuous and pinhole free conformality of the etch stop layer over a non-planar topology of the dielectric layer.

9. A method for selectively etching a silicon layer, the method comprising:
depositing an etch stop layer onto a dielectric layer of a semiconductor device;
depositing the silicon layer onto the etch stop layer; and
performing an etching process on the silicon layer using a chemical etchant, wherein the etch stop layer shields the dielectric layer from the etching process, and wherein the etching process has a selectivity ratio characterizing etch rates of the silicon layer to the etch stop layer of at least 200:1.

10. The method of claim 9, wherein the etch stop layer is deposited via a deposition process selected from the group consisting of: an atomic layer deposition process, low pressure chemical vapor deposition, and plasma enhanced chemical vapor deposition.

11. The method of claim 9, wherein the etching process is a plasma etching process.

12. The method of claim 9, wherein the etch stop layer comprises at least one material selected from the group consisting of hafnium oxide and zirconium oxide.

13. The method of claim 12, wherein the at least one material is hafnium oxide.

14. The method of claim 9, further comprising:
depositing a photoresist onto the silicon layer prior to the etching process, wherein the photoresist shields a portion of the silicon layer from the etching process.

15. A capacitor, comprising:
an etch stop layer positioned between a doped polysilicon layer and a plurality of dielectric layers arranged in series on a semiconductor substrate, wherein a selectivity ratio of the doped polysilicon layer to the etch stop layer is at least 200:1.

16. The capacitor of claim 15, wherein a dielectric constant value of the etch stop layer is greater than or equal to a dielectric constant value of a dielectric layer from the plurality of dielectric layers, and wherein the dielectric constant value of the dielectric layer is smallest amongst the plurality of dielectric layers.

17. The capacitor of claim 15, wherein the etch stop layer comprises at least one material selected from the group consisting of hafnium oxide and zirconium oxide.

18. The capacitor of claim 15, wherein the etch stop layer is positioned on a low temperature oxide layer from the plurality of dielectric layers.

19. The capacitor of claim 15, wherein the doped polysilicon layer is a top plate of the capacitor.

20. The capacitor of claim 19, further comprising a metal layer positioned on the doped polysilicon layer, wherein a periphery of the metal layer is set back a defined distance from a periphery of the doped polysilicon layer.
